(19) United States
(12) Patent Application Publication
(10) Pub. No.: US 2001/0004214 A1
(43) Pub. Date: Jun. 21, 2001

(54) Method and apparatus for determining the flow rate of a medium in a measuring tube

(76) Inventor: Thomas Budmiger, Ettingen (CH)

Correspondence Address: BOSE MCKINNEY & EVANS LLP, 135 N PENNSYLVANIA ST, SUITE 2700, INDIANAPOLIS, IN, 46204, US

(21) Appl. No.: 09/739,035

(22) Filed: Dec. 14, 2000

Related U.S. Application Data
(60) Provisional application No. 60/179,631, filed on Feb. 1, 2000.

(30) Foreign Application Priority Data
Dec. 15, 1999 (EP) 99 12 4976.4

(51) Int. Cl. G01R 27/04; G01R 27/32

(52) U.S. Cl. 324/632

(57) ABSTRACT

The invention relates to a electromagnetic method (and an apparatus) for determining the flow rate of a medium in a measuring tube (2), the medium flowing through the measuring tube (2) essentially in the direction of the measuring tube axis (10), a magnetic field permeating the measuring tube (2) essentially perpendicularly to the measuring tube axis (10), a measurement voltage being induced in at least one measuring electrode (3; 4) arranged essentially perpendicularly to the measuring tube axis (10), and the induced measurement voltage yielding information about the volumetric flow of the medium in the measuring tube (2).

The invention is based on the object of proposing a method and an apparatus which make it possible automatically to identify a malfunction on a electromagnetic flowmeter (1).

With regard to the method, the object is achieved by virtue of the fact that a defined test signal is passed to the measuring electrode (3; 4) and that using the response signal to the defined test signal (→actual value) and/or using a reference variable (→actual value) determined from the response signal to the defined test signal, it is ascertained whether the measuring electrode (3; 4) yields correct measured values.

The invention relates to a method for determining the flow rate of a medium in a measuring tube, the medium flowing through the measuring tube essentially in the direction of the measuring tube axis, a magnetic field permeating the measuring tube essentially perpendicularly to the measuring tube axis, a measurement voltage being induced in at least one measuring electrode arranged essentially perpendicularly to the measuring tube axis, and the induced measurement voltage yielding information about the volumetric flow of the medium in the measuring tube. Furthermore, the invention relates to an apparatus for determining the flow rate of a medium in a measuring tube.

Electromagnetic flowmeters utilize the principle of electrodynamic induction for volumetric flow measurement: charge carriers of the medium which are moved perpendicularly to a magnetic field induce a voltage in measuring electrodes which are likewise arranged essentially perpendicularly to the flow direction of the medium. This voltage induced in the measuring electrodes is proportional to the flow velocity of the medium averaged over the cross section of the tube; it is thus proportional to the volumetric flow.

The measuring electrodes are coupled either electrically or capacitively to the medium. If the measuring electrodes come into contact with the medium, then a coating is formed on the surface of the measuring electrodes over the course of time. The formation of the coating results in a malfunction of the flowmeter. If the coating is composed of a nonconductive material, then the flowmeter no longer yields any measured values at all.

Although the text below always describes the formation of the coating on the measuring electrode as the cause of the malfunction or lack of functioning of the flowmeter, the invention can also generally be used to identify other malfunctions that may occur on a electromagnetic flowmeter.

In order to remove undesirable coatings of conductive material from the measuring electrodes, EP 0 337 292 proposes cleaning the measuring electrodes at predetermined time intervals by the application of an electrical DC or AC voltage. Despite the appreciable advantages of automatic cleaning of the measuring electrodes compared with manual cleaning, the known automatic cleaning of the measuring electrodes also has disadvantages: first, it cannot be used universally for coatings composed of any materials—it functions only in the context of eliminating conductive coatings. Furthermore, automatic cleaning is effected preventively at predetermined time intervals; therefore, there is no guarantee that the cleaning will be effected at a point in time when it is urgently necessary.

Preventive cleaning of the measuring electrodes is disruptive and undesirable for a number of reasons: thus, volumetric flow measurement is not possible within a certain period of time after the cleaning process, since the measurement voltage first has to build up again across the measuring electrodes. Furthermore, the supply of power for the purpose of cleaning the measuring electrodes is effected for a fixedly predetermined duration, since the degree to which the coating has formed is largely unknown at the time of cleaning. It is thus left to chance or appropriate experience of the operating personnel as to whether the desired optimum state of the measuring electrodes is actually achieved after automatic cleaning. Normally, it may be assumed that after automatic cleaning, either there is still a coating on the measuring electrode or the measuring electrode has been damaged due to the cleaning voltage having been applied for too long.

The interruptions in the measurement process make an even more serious difference if the measuring electrodes have to be freed of non-conductive coatings as a precaution. The down times of the flowmeter are even longer in this case since non-conductive coatings can only be removed mechanically, that is to say that the flowmeter has to be dismantled and the measuring electrodes have to be cleaned manually.

The invention is based on the object of proposing a method and an apparatus which make it possible automatically to identify a malfunction on a electromagnetic flowmeter.

With regard to the method, the object is achieved by virtue of the fact that a defined test signal is passed to the measuring electrode and that using the response signal to the defined test signal and/or using a reference variable determined from the response signal to the defined test signal, it is ascertained whether the measuring electrode yields correct measured values. The response signal to the defined test signal and/or the reference variable determined from the response signal to the defined test signal are referred to below as actual value, for the sake of simplicity. By means of the method according to the invention, an insidious onset of a malfunction of the flowmeter is identified early on, so that it can subsequently be counteracted in a targeted manner.

One advantageous development of the method according to the invention proposes that the respective actual value is compared with a predetermined desired value and that a malfunction is indicated and/or output and/or stored if the actual value deviates from the desired value.

A preferred embodiment of the method according to the invention provides for a malfunction to be indicated and/or output only when the actual value lies outside a predetermined tolerance range around the desired value. The onset of disturbances in the measuring operation of a flowmeter is usually an insidious one, an actual malfunction being realized only when the measured values exceed the predetermined tolerances. The formation of the coating on the measuring electrode or on the measuring electrodes shall be mentioned as an example of a malfunction that occurs in such an insidious way.

It has been found that it is very advantageous if the desired value is determined, and stored, as a function of the respective process and/or system conditions. As a result, by way of example, the formation of a coating on one of the measuring electrodes depends quite critically on the customary flow velocity and the nature of the medium. It is possible to optimize the identification and elimination of an imminent malfunction on the flowmeter in good time, if the desired value is chosen with reference to the respective system and process conditions. Incidentally, the formation of a non-conductive coating on a measuring electrode causes the flowmeter not to function any more. If a conductive coating is involved, then the flowmeter yields erroneous measured values.

In the event of a conductive coating being formed on the measuring electrode, it is particularly expedient if a circuit arrangement for automatically cleaning the measuring electrode is activated as soon as a malfunction is indicated and/or output. If automatic cleaning of the measuring electrode is possible, then a preferred embodiment of the method according to the invention provides for the automatic cleaning of the measuring electrode to be effected by the application of a direct or alternating current. A corresponding circuit arrangement has been disclosed in EP 0 337 292 B1.

To ensure that the measuring electrode is damaged as little as possible by the cleaning process, one advantageous development of the method according to the invention provides for the time for the automatic cleaning of the measuring electrodes to be selected such that the coating is removed largely completely from the measuring electrode.

In the event that the malfunction occurs on account of the formation of a conductive or non-conductive coating on the measuring electrode, an advantageous embodiment of the method according to the invention provides for indication and/or outputting to be effected to the effect that the measuring electrode must be cleaned.

With regard to the apparatus, the object is achieved by virtue of the fact that the evaluation/control unit passes a test signal to at least one measuring electrode and that the evaluation/control unit uses the response signal and/or uses a representative reference variable, determined from the response signal, to determine whether the measuring electrode is yielding correct measured values. As already mentioned above, the response signal to the defined test signal and/or the reference variable determined from the response signal to the defined test signal are designated below as actual value, for the sake of simplicity.

An advantageous development of the apparatus according to the invention proposes that the test signal is preferably a square-wave pulse, that the evaluation/control unit compares the respectively determined actual value with a corresponding predetermined desired value and, from a deviation between the respectively determined actual value and the predetermined desired value, identifies a malfunction of the measuring electrode and/or forwards it to an indicating unit and/or outputs it.

A preferred development of the apparatus according to the invention provides for the test signal to be a square-wave pulse of defined length, for the evaluation/control unit to determine the relaxation time until the signal level of the response signal to the square-wave pulse reaches a predetermined threshold value, for the evaluation/control unit to compare the relaxation time (→actual value) that has been determined with a predetermined relaxation time (→desired value) and to indicate and/or output a malfunction if the actual value deviates from the predetermined desired value.

Furthermore, an expedient embodiment of the apparatus according to the invention suggests that the evaluation/control unit indicates and/or outputs a malfunction only if the actual value that has been determined lies outside a predetermined tolerance value around the desired value. The advantages of this variant have already been discussed in connection with the correspondingly configured method.

In accordance with a preferred development of the apparatus according to the invention, the evaluation/control unit determines the desired value under the respectively applicable process and/or system conditions, by passing a defined test signal to the measuring electrode and by storing and/or outputting and/or evaluating the response signal to the test signal and/or a reference variable, which is unambiguously determined using the response signal, as desired value.

The invention is explained in more detail with reference to the following drawings, in which:

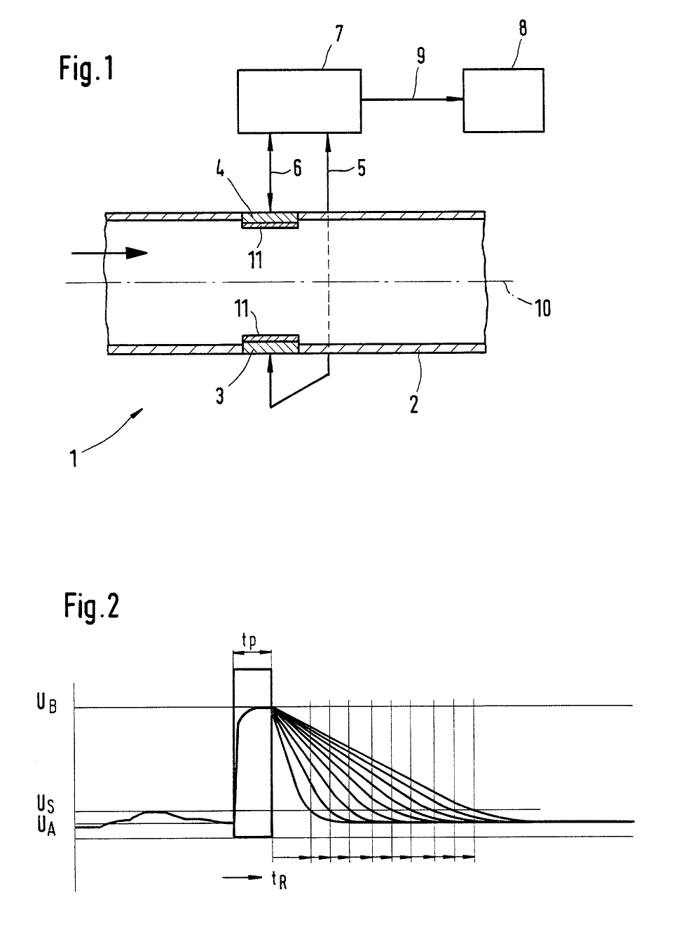

FIG. 1 shows a schematic illustration of the apparatus according to the invention,

FIG. 2 shows an illustration of the relaxation behavior of the electrode potentials at the measuring electrodes for varying degrees of coating formation, and

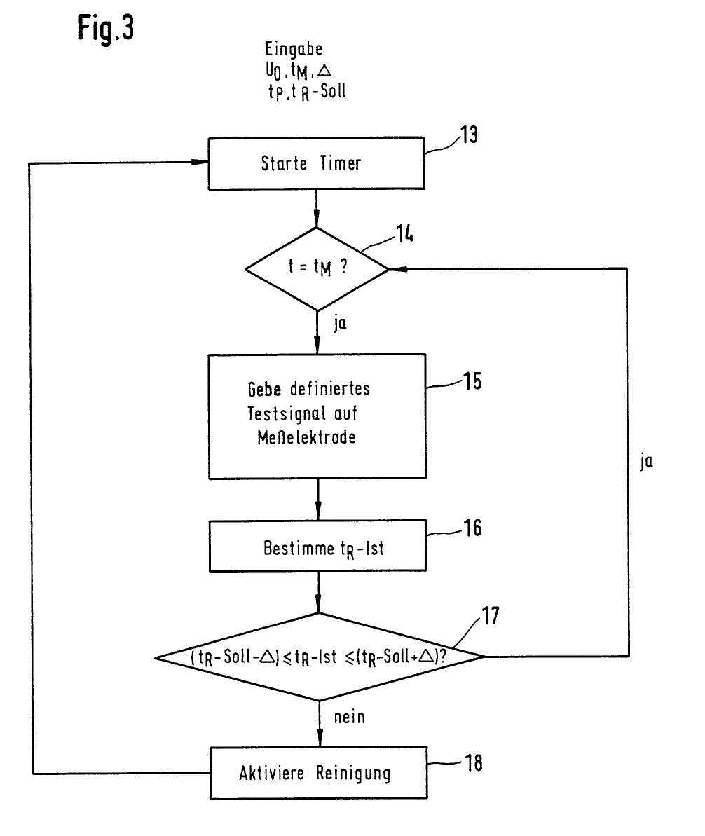

FIG. 3 shows a flow diagram relating to the driving of the evaluation/control unit.

FIG. 1 shows a schematic illustration of the apparatus 1 according to the invention. The measuring tube 2 of a flowmeter (not illustrated separately in the invention) has a medium (likewise not illustrated separately) flowing through it in the direction of the measuring tube axis 10. The medium is electrically conductive at least to a slight extent. The measuring tube 2 itself is produced from a non-conductive material, or at least its inside is lined with a non-conductive material. On account of a magnetic field which is oriented perpendicularly to the flow direction of the medium and is usually generated by two diametrically arranged electromagnets, which likewise cannot be seen in the drawing, charge carriers located in the medium migrate to the measuring electrode 3; 4 of opposite polarity. The voltage that builds up between the two measuring electrodes 3, 4 is proportional to the flow velocity of the medium averaged over the cross section of the measuring tube 2, in other words it is a measure of the volumetric flow of the medium in the measuring tube 2. Incidentally, the measuring tube 2 is connected, via connecting elements which are not illustrated separately in the drawing, to a tube system through which the medium flows.

In the case shown, the two measuring electrodes 3, 4 are in direct contact with the medium 2, as a result of which a coating 11, 12 consisting of particles of the medium is formed on the measuring electrodes 3, 4 over the course of time. Of course, this formation of a coating influences the values of the induced voltage measured at the measuring electrodes 3, 4. If the coating is made of a non-conductive material, then the flowmeter no longer functions at all.

In order to keep errors in the measurement of the volumetric flow within predetermined tolerance limits, it has been customary heretofore to clean the measuring electrodes 3, 4 of the flowmeter in each case after a fixedly predetermined period of time. The disadvantages of these time intervals, determined on an empirical basis, between the individual cleaning processes have—as already mentioned above—a number of serious disadvantages.

The measuring electrodes 3, 4 are connected to the evaluation/control unit 7 via connecting lines 5, 6. According to the invention, the evaluation/control unit 7 passes a test signal, a square-wave pulse in the simplest case, via the connecting lines 5, 6 to the measuring electrodes 3, 4. From the relaxation time of the measurement pulse, with reference to a desired value determined beforehand, it is possible to identify whether an undesirable coating has formed on the measuring electrode 3 or 4. In this case, relaxation time always means the period of time until the response signal to the test signal (e.g. the square-wave pulse) has reached a predetermined threshold value.

In order to obtain a reliable statement regarding the respective state of the measuring electrode or of the measuring electrodes, the respective actual value of the relaxation time is compared with the desired value of the relaxation time at periodic time intervals. This makes it possible to follow the genesis of the formation of the coating and to identify when predetermined tolerance values around the desired value are exceeded.

Incidentally, the desired value of the relaxation time is determined as a function of the respectively prevailing system and process conditions with measuring electrodes 3, 4 which are as clean as possible. Owing to the dependence of the relaxation time on the respective process and system conditions, it is very advantageous if the ‘identification of the formation of the coating’ is calibrated in the process itself. This calibration is effected e.g. by the repeated application of test signals (e.g. square-wave pulses) of different length and the subsequent measurement of the relaxation time. The pulse duration of the test signals is changed until the relaxation time is within a defined time window. The pulse duration of the test signal that results from this series of measurements and the associated relaxation time are stored as desired values for the subsequent measurements for the purpose of identifying the formation of the coating.

If, during subsequent periodic measurements for the purpose of identifying the formation of the coating, it turns out that the actual value of the relaxation time in response to the defined test signal lies outside certain tolerance limits around the desired value of the relaxation time, a malfunction is indicated on the indicating unit 8 of the flowmeter; as an alternative, in the event of conductive coatings being formed, an automatic cleaning procedure can be activated.

According to the invention, the cleaning of the measuring electrodes 3, 4 or the indication that cleaning of the measuring electrodes 3, 4 is necessary can always be effected when the formation of the coating which occurs on the measuring electrodes 3, 4 becomes so severe that it leads to unacceptable corruption of the measured values at the measuring electrodes 3, 4. This means that it is possible to optimize the period of time between two cleaning processes: thus, on the one hand, cleaning is effected before the flowmeter yields erroneous measured values or, in the case of non-conductive coatings 11, 12, before it no longer yields any measured values at all; on the other hand, cleaning is effected only when it is actually necessary, rather than preventively after certain time intervals based on some empirical experience.

FIG. 2 shows an illustration of the relaxation behavior of the electrode potentials at the measuring electrodes 3, 4 with different degrees of coating formation. A square-wave pulse U_{O} having a defined duration t_{P} is passed to the measuring electrode 3; 4. The evaluation/control unit measures the relaxation time t_{R}, that is to say it measures the time which elapses until the square-wave pulse U_{O} has fallen to a predetermined threshold value U_{S}. As soon as the actual value of the relaxation time t_{R}-actual exceeds a predetermined tolerance value ±Δt around the desired value of the relaxation time t_{R}-desired, either automatic cleaning of the measuring electrode 3; 4 is performed or the operating personnel are alerted, via the indicating unit 8, of the fact that the measuring electrode 3; 4 should be cleaned. FIG. 3 illustrates a flow diagram relating to the driving of the evaluation/control unit 7. At the beginning of the measurements, the voltage of the test signal U_{O}, the pulse duration of the test signal t_{P}, the tolerance value of the relaxation time At, the period of time between two successive test signals t_{M}, the pulse duration t_{P} and the desired value of the relaxation time t_{R}-desired are made available as input values to the evaluation/control unit 7. As already described above, the pulse duration of the test signal t_{P} and the desired value of the relaxation time t_{R}-desired are determined as system—and process—dependent reference variables at the beginning of the actual method for the purpose of identifying the formation of the coating. Consequently, the calibration is effected only in the process. The subsequently measured actual values of the relaxation time t_{R}-actual are always referred to this system—and process—dependent desired value of the relaxation time t_{R}-desired, in order to identify the formation of the coating on the measuring electrode 3; 4 as early as possible.

The program successively executes the following program points: at program point 13, the timer is started. As already mentioned a number of times, a test signal is passed to the measuring electrode 3, 4 at regular time intervals t_{M} (program points 14, 15). The actual value of the relaxation time t_{R}-actual is subsequently determined at program point 16. At point 17, a check is made to see whether the actual value that has been determined for the relaxation time t_{R}-actual lies within the tolerance limits Δt around the desired value of the relaxation time t_{R}-desired. If this is the case, then the program jumps to program point 14 and, once the time period tM has elapsed, starts a renewed measurement process for determining the actual value of the relaxation time t_{R}-actual. If the actual value of the relaxation time t_{R}-actual lies outside the predetermined tolerance limits Δt around the desired value of the relaxation time t_{R}-desired, then the cleaning of the measuring electrodes 3, 4 is initiated at point 18. Once the cleaning process has ended, the program starts the timer again.

1. An electromagnetic method for determining the flow rate of a medium in a measuring tube, the medium flowing through the measuring tube essentially in the direction of the measuring tube axis, a magnetic field permeating the measuring tube essentially perpendicularly to the measuring tube axis, a measurement voltage being induced in at least one measuring electrode arranged essentially perpendicularly to the measuring tube axis, and the induced measurement voltage yielding information about the volumetric flow of the medium in the measuring tube, wherein a defined test signal is passed to the measuring electrode (3; 4) and using the response signal to the defined test signal (→actual value) and/or using a reference variable (→actual value) determined from the response signal to the defined test signal, it is ascertained whether the measuring electrode (3; 4) provides correct measured values.

2. The method as claimed in claim 1,
wherein the respective actual value is compared with a corresponding predetermined desired value and a malfunction is indicated and/or output and/or stored if the actual value deviates from the desired value.

3. The method as claimed in claim 1 or 2,
wherein a malfunction is indicated and/or output only when the actual value lies outside a predetermined tolerance value (A) around the desired value.

4. The method as claimed in claim 1,
wherein the desired value is determined, and stored, as a function of the respective process and/or system conditions.

5. The method as claimed in claims 1 to 4,
wherein in the event that the malfunction occurs on account of the formation of a conductive coating (11, 12) on the measuring electrode (3; 4), automatic cleaning of the measuring electrode is activated as soon as a malfunction is indicated and/or output.

6. The method as claimed in claims 1 to 4,
wherein in the event that the malfunction occurs on account of the formation of a conductive or non-conductive coating (11; 12) on the measuring electrode (3; 4), indication and/or outputting is effected to the effect that the measuring electrode (3; 4) must be cleaned.

7. The method as claimed in claim 5,
wherein the automatic cleaning of the measuring electrode (3; 4) is effected by the application of a direct or alternating current.

8. The method as claimed in claim 5 or 7,
wherein the time for the automatic cleaning of the measuring electrodes (3; 4) is selected such that the coating (11; 12) is removed largely completely from the measuring electrode (3; 4).

9. An apparatus for measuring the flow of a medium which flows through a measuring tube in the direction of the measuring tube axis, having a magnetic arrangement which generates a magnetic field which permeates the measuring tube and runs essentially transversely with respect to the measuring tube axis, having a measuring electrode arrangement which yields a measured value which is dependent on the flow velocity of the medium through the measuring tube, and having a control/evaluation unit which determines the flow rate of the medium in the measuring tube from the measured value,
wherein the evaluation/control unit (7) passes a test signal to at least one measuring electrode (3; 4) and
the evaluation/control unit (7) uses the response signal (→actual value) and/or uses a representative reference variable (→actual value), determined from the response signal, to determine whether the measuring electrode (3; 4) is yielding correct measured values and/or whether the flowmeter is operating correctly.

10. The apparatus as claimed in claim 9,
wherein the test signal is preferably a square-wave pulse, the evaluation/control unit (7) compares the respectively determined actual value with a corresponding predetermined desired value and, from a deviation between the respectively determined actual value and the predetermined desired value, identifies a malfunction of the measuring electrode (3; 4) and/or forwards it to an indicating unit (8) and/or outputs it.

11. The apparatus as claimed in claim 9, the test signal is a square-wave pulse, the evaluation/control unit (7) determines the relaxation time (t_{R}-actual) until the signal level of the response signal to the square-wave pulse reaches a predetermined threshold value (U_{S}),
the evaluation/control unit (7) compares the actual value of the relaxation time (t_{R}-actual) with a predetermined desired value of the relaxation time (t_{R}-desired) and indicates and/or outputs a malfunction if the actual value (t_{R}-actual) deviates from the predetermined desired value (t_{R}-desired).

12. The apparatus as claimed in claim 10 or 11,
wherein the evaluation/control unit (7) indicates and/or outputs a malfunction only if the actual value that has been determined lies outside a predetermined tolerance value around the desired value.

13. The apparatus as claimed in claim 12,
wherein the evaluation/control unit (7) determines the desired value under the respectively applicable process and/or system conditions, by passing a defined test signal to the measuring electrode (3; 4) and by storing and/or outputting and/or evaluating the response signal to the test signal and/or a reference variable, which is unambiguously determined using the response signal, as desired value.
